(19) United States
(12) Patent Application Publication
(10) Pub. No.: US 2024/0088031 A1
(43) Pub. Date: Mar. 14, 2024

(54) MICROELECTRONIC DEVICES INCLUDING STAIRCASE STRUCTURES, AND RELATED METHODS, MEMORY DEVICES, AND ELECTRONIC SYSTEMS

(71) Applicant: Micron Technology, Inc., Boise, ID (US)

(72) Inventors: Lifang Xu, Boise, ID (US); Bo Zhao, Boise, ID (US); Jeffrey D. Runia, Boise, ID (US); Nancy M. Lomeli, Boise, ID (US)

(21) Appl. No.: 17/930,656

(22) Filed: Sep. 8, 2022

(51) Int. Cl. H01L 23/528; H01L 21/768; H01L 23/535

(52) U.S. Cl. CPC H01L 23/5283; H01L 21/76816; H01L 21/76895; H01L 23/535

(57) ABSTRACT

A microelectronic device includes a stack structure including a block region and a non-block region. The block region includes blocks separated from one another in a first horizontal direction by insulative slot structures and each including a vertically alternating sequence of conductive material and insulative material arranged in tiers. At least one of the blocks has stadium structures individually including staircase structures having steps comprising edges of some of the tiers. The non-block region neighbors the block region in the first horizontal direction. The non-block region includes additional stadium structures individually terminating at a relatively higher vertical position within the stack structure than at least one of the stadium structures at least partially within boundaries thereof in a second horizontal direction orthogonal to the first horizontal direction. Related memory devices, electronic systems, and methods are also described.

### TECHNICAL FIELD

The disclosure, in various embodiments, relates generally to the field of microelectronic device design and fabrication. More specifically, the disclosure relates to methods of forming microelectronic devices including staircase structures, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices, such as Flash memory devices. A conventional Flash memory device generally includes a memory array having charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a “three-dimensional NAND” memory device (which may also be referred to herein as a “3D NAND” memory device), a type of vertical memory device, not only are the memory cells arranged in row and column fashion in a horizontal array, but tiers of the horizontal arrays are stacked over one another (e.g., as vertical strings of memory cells) to provide a “three-dimensional array” of the memory cells. The stack of tiers vertically alternate conductive materials with insulative (e.g., dielectric) materials. The conductive materials function as control gates for access lines (e.g., word lines) of the memory cells. Vertical structures (e.g., pillars comprising channel structures and tunneling structures) extend along the vertical string of memory cells. A drain end of a string is adjacent one of the top and bottom of the vertical structure, while a source end of the string is adjacent the other of the top and the bottom of the pillar. The drain end is operably connected to a bit line, while the source end is operably connected to a source structure (e.g., a source plate, a source line). A 3D NAND memory device also includes electrical connections between, the access lines and other conductive structures of the device so that the memory cells of the vertical strings can be selected for writing, reading, and erasing operations.

Some 3D NAND memory devices include so-called “staircase” structures having “steps” (also referred to as “stairs”) at edges (e.g., ends) of the tiers of the stack. The steps have treads (e.g., upper surfaces) defining contact regions of conductive structures of the device, such as of access lines (e.g., local access lines), which may be formed by the conductive materials of the tiered stack. Contact structures may be provided in physical contact with the steps to facilitate electrical access to the conductive structures associated with the steps. The contact structures may be in electrical communication, by way of conductive routing structures, to additional contact structures that communicate to a source/drain region. String drivers drive access line voltages to write to or read from the memory cells controlled via the access lines.

A continued goal in the microelectronic device fabrication industry is to reduce the footprint of the features of microelectronic devices so as to maximize the number of devices, and functional features thereof, in a given structural area. Unfortunately, as feature packing densities have increased and margins for formation errors have decreased, conventional fabrication methods and resulting structural configurations have resulted in undesirable defects that can diminish desired memory device performance, reliability, and durability.

### BRIEF DESCRIPTION OF THE DRAWINGS

FIG. 1A is a simplified, longitudinal cross-sectional view a microelectronic device structure at a processing stage of a method forming a microelectronic device, in accordance with embodiments of the disclosure. FIG. 1B is a simplified, partial top-down view of the microelectronic device structure at the processing stage of FIG. 1A, wherein the view of FIG. 1A is about the dashed line A-A depicted in FIG. 1B.

FIG. 2A is a simplified, longitudinal cross-sectional view of the microelectronic device structure shown in FIGS. 1A and 1B at another processing stage of the method forming the microelectronic device following the processing stage of FIGS. 1A and 1B. FIG. 2B is a simplified, partial top-down view of the microelectronic device structure at the processing stage of FIG. 2A, wherein the view of FIG. 2A is about the dashed line A-A depicted in FIG. 2B.

FIG. 3A is a simplified, longitudinal cross-sectional view of the microelectronic device structure shown in FIGS. 1A and 1B at another processing stage of the method forming the microelectronic device following the processing stage of FIGS. 2A and 2B. FIG. 3B is a simplified, partial top-down view of the microelectronic device structure at the processing stage of FIG. 3A.

FIG. 4A is a simplified, longitudinal cross-sectional view of the microelectronic device structure shown in FIGS. 1A and 1B at another processing stage of the method forming the microelectronic device following the processing stage of FIGS. 3A and 3B. FIG. 4B is a simplified, partial top-down view of the microelectronic device structure at the processing stage of FIG. 4A, wherein the view of FIG. 4A is about the dashed line A-A depicted in FIG. 4B.

FIG. 4C is a simplified, partial perspective view of a portion B (identified with dashed lines in FIG. 4A) of the microelectronic device structure at the processing stage of FIG. 4A.

FIG. 5A is a simplified, longitudinal cross-sectional view of a microelectronic device structure at a processing stage of a method forming a microelectronic device, in accordance with additional embodiments of the disclosure. FIG. 5B is a simplified, partial top-down view of the microelectronic device structure at the processing stage of FIG. 5A, wherein the view of FIG. 5A is about the dashed line A-A depicted in FIG. 5B.

FIG. 6 is a simplified partial cutaway perspective view of a microelectronic device, in accordance with embodiments of the disclosure.

FIG. 7 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessary limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, materials, structures, trenches, devices) described as “neighboring” one another means and includes features of the disclosed identity (or identities) that are located most proximate (e.g., closest to) one another. Additional features (e.g., additional regions, additional materials, additional structures, additional trenches, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Jr), nickel (Ni), palladium (Pa), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

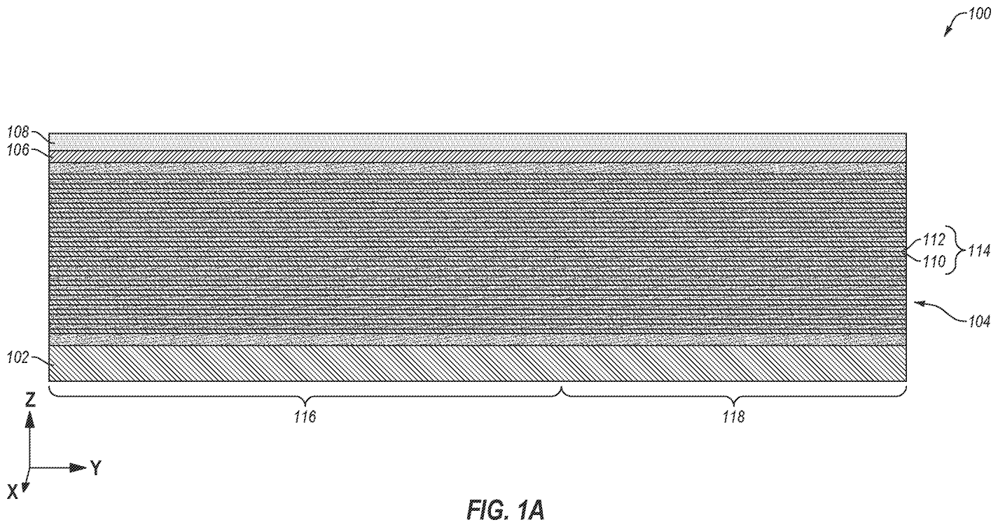

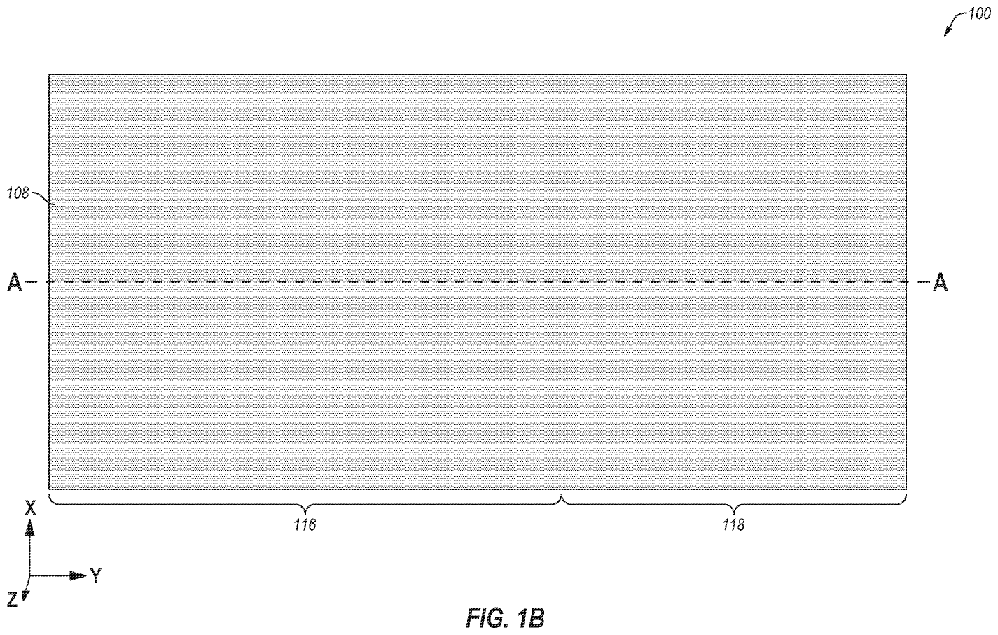

FIGS. 1A through 4C are various views (described in further detail below) illustrating a microelectronic device structure at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the methods described herein may be used for forming various devices. In other words, the methods of the disclosure may be used whenever it is desired to form a microelectronic device.

FIG. 1A depicts a simplified, longitudinal cross-sectional view of a microelectronic device structure 100. As shown in FIG. 1A, the microelectronic device structure 100 may be formed to include a base structure 102, a preliminary stack structure 104 on or over the base structure 102, a masking material 106 on or over the base structure 102, and an isolation material 108 on or over the masking material 106. FIG. 1B is a simplified, partial top-down view of the microelectronic device structure 100 at the processing stage of FIG. 1A, wherein the view of FIG. 1A is about the dashed line A-A depicted in FIG. 1B.

The base structure 102 may comprise a base material or construction upon which additional features (e.g., materials, structures, devices) of the formed. As a non-limiting example, the base structure 102 may comprise a structure (e.g., a wafer, such as semiconductor wafer) formed of and including, for example, one or more semiconductor materials (e.g., polycrystalline silicon). One or more regions of the semiconductor materials may be doped with one or more P-type conductivity chemical species (e.g., one or more of boron, aluminum, and gallium) and/or one or more N-type conductivity chemical species (e.g., one or more of arsenic, phosphorous, and antimony) to provide one or more source/drain regions of the microelectronic device structure 100. The base structure 102 may also include other base material(s) or structure(s), such as conductive regions for making electrical connections with other conductive structures of a microelectronic device to be formed from the microelectronic device structure 100 following subsequent processing. In some such embodiments, control logic devices including complementary metal-oxide-semiconductor (CMOS) circuitry are included within the base structure 102, in a control logic region vertically underlying a source/drain region.

The preliminary stack structure 104 may be formed to include a vertically alternating (e.g., in a Z-direction) sequence of sacrificial material 110 and preliminary insulative material 112 arranged in preliminary tiers 114. The preliminary tiers 114 of the preliminary stack structure 104 may individually include the sacrificial material 110 vertically neighboring (e.g., directly vertically adjacent) the preliminary insulative material 112. The sacrificial material 110 may be vertically interleaved with the preliminary insulative material 112 across a vertical height (e.g., in the Z-direction) of the preliminary stack structure 104. In addition, the preliminary stack structure 104 may include a block region 116, and a non-block region 118 (also referred to herein as a “dummy region” or an “outside-of-block” region) horizontally neighboring the block region 116. As described in further detail below, blocks of a stack structure subsequently formed from the preliminary stack structure 104 may be formed within the horizontal area of the block region 116, but may not be formed within (e.g., may be omitted from) the horizontal area of the non-block region 118.

The preliminary insulative material 112 of each of the preliminary tiers 114 of the preliminary stack structure 104 may be formed of and include at least one insulative material, such one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the preliminary insulative material 112 of each of the preliminary tiers 114 of the preliminary stack structure 104 is formed of and includes a dielectric oxide material, such as SiOₓ (e.g., SiO₂). The preliminary insulative material 112 of each of the preliminary tiers 114 may be substantially homogeneous, or the preliminary insulative material 112 of one or more (e.g., each) of the preliminary tiers 114 may be heterogeneous. As shown in FIG. 1A, a relatively vertically thicker volume of the preliminary insulative material 112 may be formed at an upper vertical boundary of the preliminary stack structure 104. The relatively vertically thicker volume of the preliminary insulative material 112 may, for example, directly vertically underlie the masking material 106.

The sacrificial material 110 of each of the preliminary tiers 114 of the preliminary stack structure 104 may be formed of and include at least one material (e.g., at least one insulative material) that may be selectively removed relative to the preliminary insulative material 112. The sacrificial material 110 may be selectively etchable relative to the preliminary insulative material 112 during common (e.g., collective, mutual) exposure to a first etchant; and the preliminary insulative material 112 may be selectively etchable to the sacrificial material 110 during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. By way of non-limiting example, depending on the material composition of the preliminary insulative material 112, the sacrificial material 110 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductor material (e.g., polycrystalline silicon). In some embodiments, the sacrificial material 110 of each of the preliminary tiers 114 of the preliminary stack structure 104 is formed of and includes a dielectric nitride material, such as SiN_{y} (e.g., Si₃N₄). The sacrificial material 110 may, for example, be selectively etchable relative to the preliminary insulative material 112 during common exposure to a wet etchant comprising phosphoric acid (H₃PO₄).

The preliminary stack structure 104 may be formed to include any desired quantity of the preliminary tiers 114. By way of non-limiting example, the preliminary stack structure 104 may be formed to include greater than or equal to sixteen (16) of the preliminary tiers 114, such as greater than or equal to thirty-two (32) of the preliminary tiers 114, greater than or equal to sixty-four (64) of the preliminary tiers 114, greater than or equal to one hundred and twenty-eight (128) of the preliminary tiers 114, or greater than or equal to two hundred and fifty-six (256) of the preliminary tiers 114.

The masking material 106 may be formed on or over an uppermost surface of the preliminary stack structure 104. The masking material 106 may at least partially (e.g., substantially) cover the uppermost surface of the preliminary stack structure 104. As shown in FIGS. 1A and 1B, masking material 106 may horizontally extend (e.g., in the X-direction and the in Y-direction) across each of the block region 116 and the non-block region 118 of the preliminary stack structure 104. In some embodiments, the masking material 106 is formed to substantially cover the uppermost surface of the preliminary stack structure 104 within each of block region 116 and the non-block region 118.

The masking material 106 may be formed of and include at least one material (e.g., at least one hard mask material) suitable for use as an etch mask to pattern portions of the preliminary stack structure 104 (e.g., portions of the preliminary tiers 114, including portions of the sacrificial material 110 and portions of the preliminary insulative material 112 thereof) to form stadium structures within the preliminary stack structure 104, as described in further detail below. As a non-limiting example, in some embodiments wherein the sacrificial material 110 comprises SiN_{y} (e.g., Si₃N₄) and the preliminary insulative material 112 comprises SiOₓ (e.g., SiO₂), the masking material 106 may be formed of and include one or more of metal-doped carbon, polycrystalline silicon, and carbon-doped nitride. If the masking material 106 is formed of and includes metal-doped carbon, the metal may, for example, comprise one or more of boron, tungsten, and nickel, and may constitute from about 1.0 weight percent (wt %) to about 30.0 wt % of the metal-doped carbon. The masking material 106 may be substantially homogeneous, or the masking material 106 may be heterogeneous.

The isolation material 108 may be formed on or over an uppermost surface of the masking material 106. The isolation material 108 may at least partially (e.g., substantially) cover the uppermost surface of the masking material 106. The isolation material 108 may be formed of and include at least one insulative material. A material composition of the isolation material 108 may be different than a material composition of the masking material 106. In some embodiments, a material composition of the isolation material 108 is selected relative to a material composition of the masking material 106 to effectively form a multi-layer masking structure (including the masking material 106 and the isolation material 108) for use as an etch mask to pattern portions of the preliminary stack structure 104 thereunder. A material composition of the isolation material 108 may be substantially the same as a material composition of the preliminary insulative material 112 of the preliminary stack structure 104, or the material composition of the isolation material 108 may be different than the material composition of the preliminary insulative material 112 of the preliminary stack structure 104. In some embodiments, the isolation material 108 is formed of and includes SiOₓ (e.g., SiO₂). In additional embodiments, the isolation material 108 is not formed to overlie the masking material 106 at the processing stage of FIGS. 1A and 1B.

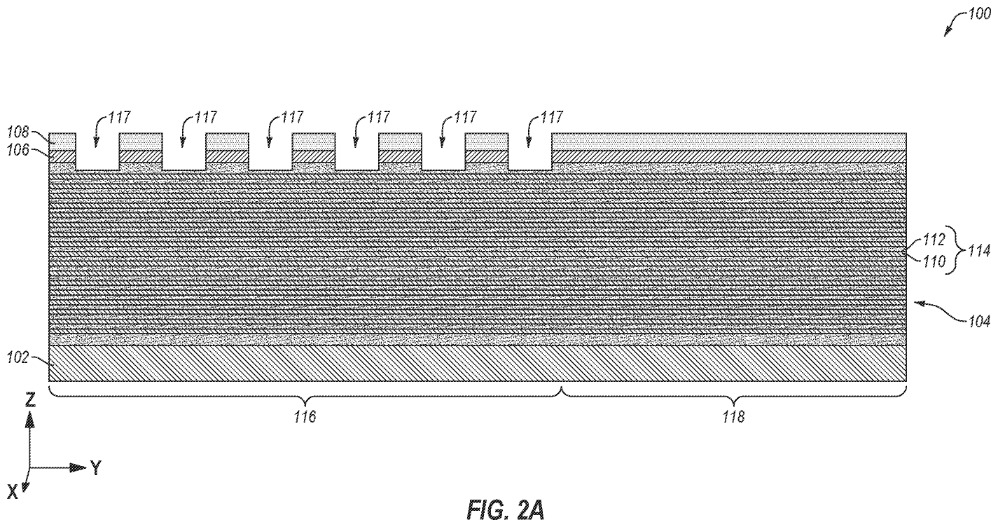

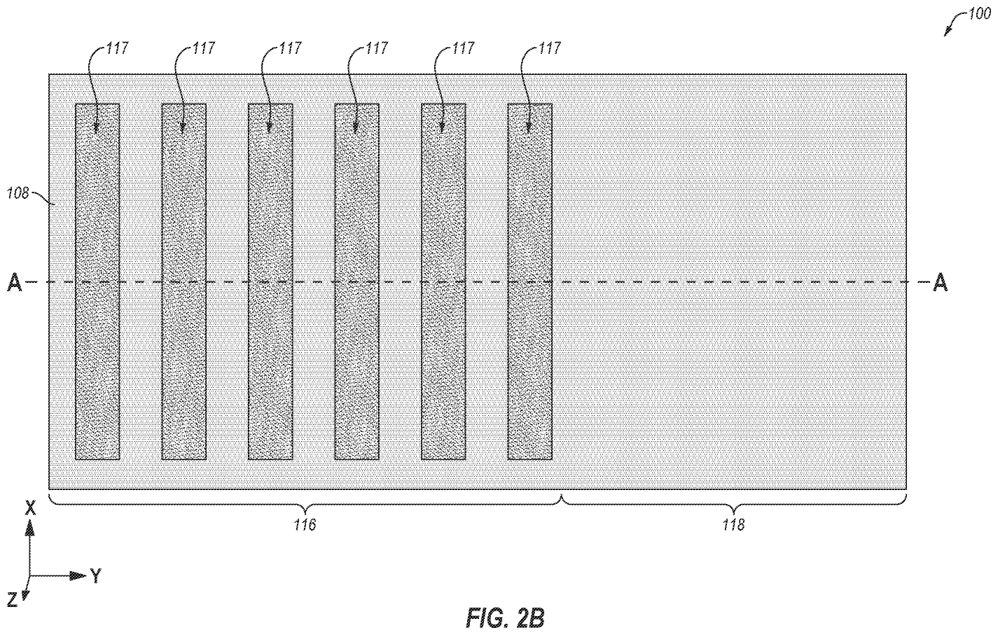

Referring next to FIG. 2A, which is a simplified, longitudinal cross-sectional view of the microelectronic device structure 100 following the processing stage previously described with reference to FIGS. 1A and 1B, portions of at least the isolation material 108 and the masking material 106 within a horizontal area of the block region 116 of the preliminary stack structure 104 may be removed to form openings 117 individually vertically extending through the isolation material 108 and the masking material 106 and to or into the preliminary stack structure 104. The openings 117 may individually vertically terminate at or below a lower boundary (e.g., lower surface) of the masking material 106, and may be confined within the horizontal area of the block region 116 of the preliminary stack structure 104. The portions of the isolation material 108 and the masking material 106 within a horizontal area of the non-block region 118 may not be removed, such that the non-block region 118 is substantially free of any of the openings 117 within the horizontal area thereof. The isolation material 108 and the masking material 106 may remain substantially intact within the horizontal area of the non-block region 118. FIG. 2B is a simplified, partial top-down view of the microelectronic device structure 100 at the processing stage of FIG. 2A, wherein the view of FIG. 2A is about the dashed line A-A depicted in FIG. 2B.

The openings 117 may be formed at horizontal positions (e.g., in the X-direction, in the Y-direction) within the block region 116 of the preliminary stack structure 104 corresponding to desired locations of stadium structures to subsequently be formed within preliminary stack structure 104, as described in further detail below. The openings 117 may be distributed throughout the horizontal area of the block region 116. Within the block region 116, rows of the openings 117 may be formed to extend in parallel in the X-direction, and columns of the openings 117 may be formed to extend in the Y-direction orthogonal to the X-direction. The rows of the openings 117 may individually include some of the openings 117 at least partially (e.g., substantially) aligned with one another in the Y-direction. The columns of the openings 117 may individually include other of the openings 117 at least partially (e.g., substantially) aligned with one another in the X-direction. Within the block region 116, different rows of the openings 117 may be positioned within different horizontal areas of the preliminary stack structure 104 to be formed into different blocks of a stack structure to be formed from the preliminary stack structure 104, as described in further detail below.

Each of the openings 117 may be formed to exhibit desirable horizontal dimensions (e.g., in the X-direction, in the Y-direction) and a desirable horizontal cross-sectional shape. The horizontal dimensions and a horizontal cross-sectional shape of an individual opening 117 may be selected based on desirable horizontal dimensions and desirable horizontal boundaries of a stadium structure to subsequently be formed within a horizontal area of the opening 117, as well as based on desirable horizontal dimensions and a desirable horizontal cross-sectional shape of a block (of a stack structure to be formed from the preliminary stack structure 104) to be formed to include the stadium structure within a horizontal area thereof, described in further detail below. As shown in FIG. 2B, in some embodiments, an individual opening 117 is formed to exhibit a rectangular horizontal cross-sectional shape, including a horizontal length in the X-direction that is larger than a horizontal width in the Y-direction. Each of the openings 117 may be formed to exhibit substantially the same horizontal dimensions (e.g., substantially the same horizontal length and substantially the same horizontal width) and substantially the same horizontal shape as each other of the openings 117, or at least one of the openings 117 may be formed to exhibit one or more of different horizontal dimension(s) (e.g., a different horizontal length and/or a different horizontal width) and a different horizontal shape than at least one other of the openings 117.

Each of the openings 117 may be formed to vertically terminate at a desired vertical position (e.g., in the Z-direction) below the masking material 106. As shown in FIG. 2A, in some embodiments, the openings 117 are formed to individually vertically terminate above the sacrificial material 110 of an uppermost preliminary tier 114 of the preliminary stack structure 104. Each of the openings 117 may be formed to vertically terminate at substantially the same vertical position as each other of the openings 117, or at least one of the openings 117 may be formed to vertically terminate at a different vertical position than at least one other of the openings 117. In some embodiments, the openings 117 are all formed to vertically terminate at substantially the same vertical position as one another.

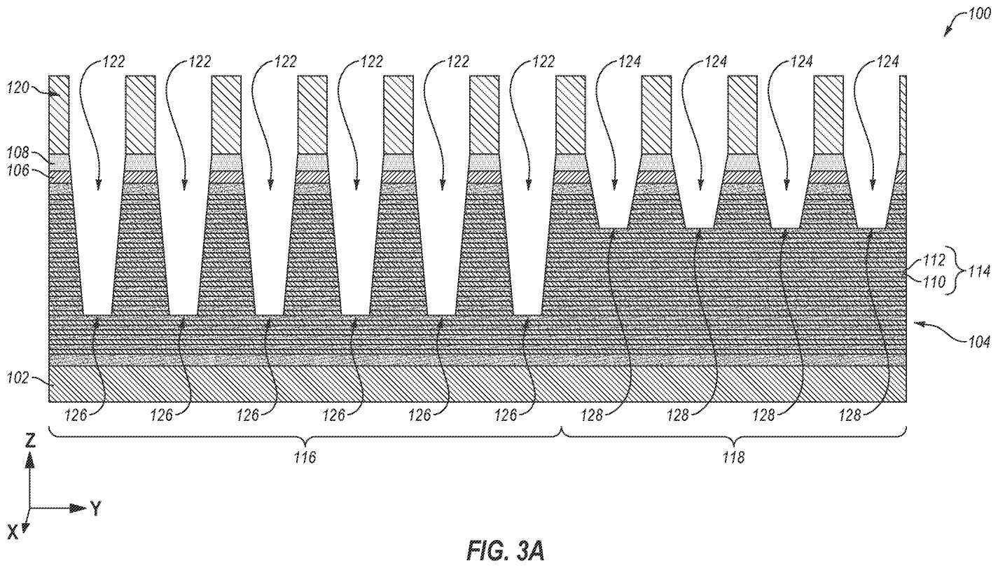

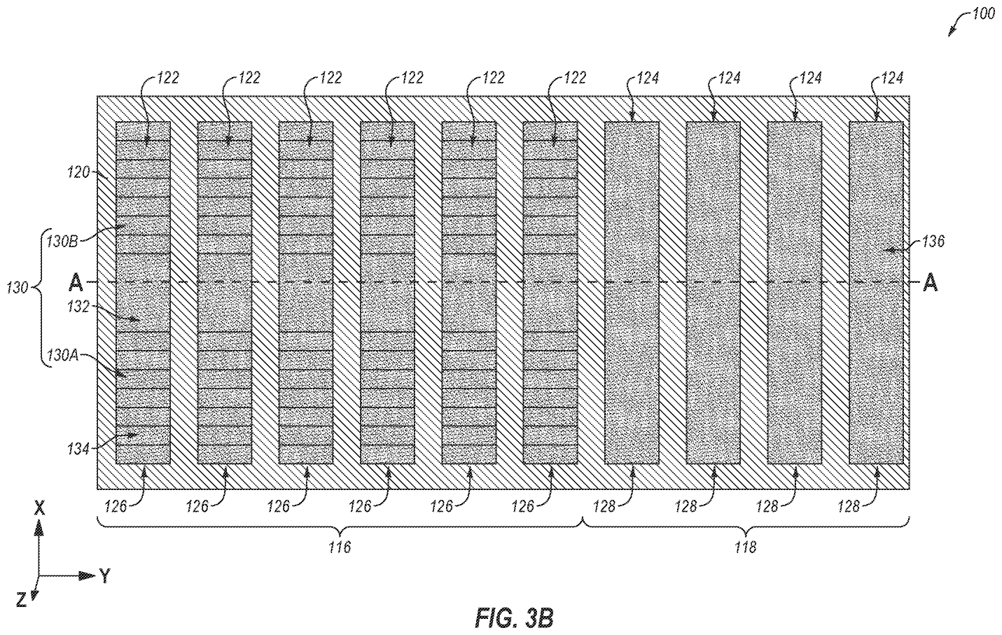

Referring next to FIG. 3A, which is a simplified, longitudinal cross-sectional view of the microelectronic device structure 100 following the processing stage previously described with reference to FIGS. 2A and 2B, at least one mask structure 120 (e.g., an etch mask structure, a chop mask structure) may be formed over the isolation material 108, and may be employed to form stadium trenches 122 within the block region 116 of the preliminary stack structure 104 and dummy stadium trenches 124 (also referred to herein as “additional stadium trenches”) within the non-block region 116 of the preliminary stack structure 104. At least some stadium trenches 122 horizontally overlapping one or more dummy stadium trenches 124 in the X-direction may be formed to have lower vertical boundaries below lower vertical boundaries of the one or more dummy stadium trenches 124. The stadium trenches 122 may at least partially define stadium structures 126 within the block region 116 of the preliminary stack structure 104; and the dummy stadium trenches 124 may at least partially define dummy stadium structures 128 (also referred to herein as “additional stadium structures”) within the non-block region 118 of the preliminary stack structure 104. FIG. 3B is a simplified, partial top-down view of the microelectronic device structure 100 at the processing stage of FIG. 3A, wherein the view of FIG. 3A is about the dashed line A-A depicted in FIG. 3B.

The mask structure 120 may be employed to protect (e.g., mask) portions of the preliminary stack structure 104 (e.g., including the preliminary tiers 114 thereof) vertically thereunder and within horizontal boundaries thereof from removal during the formation of the stadium trenches 122 and the dummy stadium trenches 124, as described in further detail below. The mask structure 120 may include apertures (e.g., openings, holes) vertically extending therethrough and horizontally positioned at desired locations of the stadium trenches 122 (and, hence, the stadium structures 126) and the dummy stadium trenches 124 (and, hence, the dummy stadium structures 128). Apertures in the mask structure 120 that are located within a horizontal area of the block region 116 of the preliminary stack structure 104 may horizontally overlap horizontal areas of the openings 117 (FIGS. 2A and 2B) within the block region 116 formed during the processing stage previously described with reference to FIGS. 2A and 2B.

The mask structure 120 may be formed of and include at least one material having etch selectively relative to the preliminary stack structure 104 (including the sacrificial material 110 and the preliminary insulative material 112 of the preliminary tiers 114 thereof), the masking material 106, the isolation material 108 (if any), and resist material formed within the openings 117 (FIGS. 2A and 2B) prior to the formation of the stadium trenches 122 and the dummy stadium trenches 124 (as described in further detail below). Accordingly, a material composition of the mask structure 120 may at least partially depend on material compositions of the preliminary stack structure 104, the masking material 106, the isolation material 108 (if any), and the resist material; and on characteristics (e.g., etchant(s)) of the material removal process to be employed with the mask structure 120. By way of non-limiting example, the mask structure 120 may be formed of and include one or more of amorphous carbon, silicon, a silicon oxide, a silicon nitride, a silicon oxycarbide, aluminum oxide, and a silicon oxynitride. The mask structure 120 may be homogeneous (e.g., may comprise only one material), or may be heterogeneous (e.g., may comprise a stack of at least two different materials).

The stadium trenches 122 may be located at horizontal positions (e.g., in the X-direction, in the Y-direction) of the openings 117 (FIGS. 2A and 2B) formed at the processing stage previously described with reference to FIGS. 2A and 2B, and may vertically extend to desirable depths within the block region 116 of the preliminary stack structure 104. At least some of the stadium trenches 122 may vertically extend to and terminate at different preliminary tiers 114 of the preliminary stack structure 104 than at least some other of the stadium trenches 122. For example, at least some (e.g., each) of the stadium trenches 122 of an individual row of the stadium trenches 122 extending in the X-direction may be formed to terminate at different vertical elevations in the Z-direction than one another. However, as shown in FIG. 3A, at least some (e.g., each) of the stadium trenches 122 of an individual column of the stadium trenches 122 extending in the Y-direction may terminate at substantially the same vertical elevation in the Z-direction as one another.

The stadium structures 126 may be positioned within horizontal areas of the stadium trenches 122, and may be exposed by the stadium trenches 122. Referring to FIG. 3B, an individual stadium structure 126 may include opposing staircase structures 130, and a central region 132 horizontally interposed between (e.g., in the X-direction) the opposing staircase structures 130. The opposing staircase structures 130 of an individual stadium structure 126 may include a forward staircase structure 130A and a reverse staircase structure 130B. A phantom line extending from a top of the forward staircase structure 130A to a bottom of the forward staircase structure 130A may have a positive slope, and another phantom line extending from a top of the reverse staircase structure 130B to a bottom of the reverse staircase structure 130B may have a negative slope. In additional embodiments, one or more of the stadium structures 126 may individually exhibit a different configuration. As a non-limiting example, an individual stadium structure 126 may be modified to include a forward staircase structure 130A but not a reverse staircase structure 130B (e.g., the reverse staircase structure 130B may be absent), an individual stadium structure 126 may be modified to include a reverse staircase structure 130B but not a forward staircase structure 130A (e.g., the forward staircase structure 130A may be absent). In such embodiments, the central region 132 horizontally neighbors a bottom of the forward staircase structure 130A (e.g., if the reverse staircase structure 130B is absent), or the central region 132 horizontally neighbors a bottom of the reverse staircase structure 130B (e.g., if the forward staircase structure 130A is absent).

The opposing staircase structures 130 (e.g., the forward staircase structure 130A and the reverse staircase structure 130B) of an individual stadium structure 126 may each include steps 134 defined by edges (e.g., horizontal ends) some of the preliminary tiers 114 (FIG. 3A) of the preliminary stack structure 104 (FIG. 3A). For the opposing staircase structures 130 of an individual stadium structure 126, each step 134 of the forward staircase structure 130A may have a counterpart step 134 within the reverse staircase structure 130B having substantially the same geometric configuration (e.g., shape, dimensions), vertical position (e.g., in the Z-direction), and horizontal distance (e.g., in the X-direction) from a horizontal center (e.g., in the X-direction) of the central region 132 of the stadium structure 126. In additional embodiments, at least one step 134 of the forward staircase structure 130A does not have a counterpart step 134 within the reverse staircase structure 130B having substantially the same geometric configuration (e.g., shape, dimensions), vertical position (e.g., in the Z-direction), and/or horizontal distance (e.g., in the X-direction) from horizontal center (e.g., in the X-direction) of the central region 132 of the stadium structure 126; and/or at least one step 134 of the reverse staircase structure 130B does not have a counterpart step 134 within the forward staircase structure 130A having substantially the same geometric configuration (e.g., shape, dimensions), vertical position (e.g., in the Z-direction), and/or horizontal distance (e.g., in the X-direction) from horizontal center (e.g., in the X-direction) of the central region 132 of the stadium structure 126.

Each of the stadium structures 126 within the block region 116 of the preliminary stack structure 104 (FIG. 3A) may individually include a desired quantity of steps 134. Each of the stadium structures 126 may include substantially the same quantity of steps 134 as each other of the stadium structures 126, or at least one of the stadium structures 126 may include a different quantity of steps 134 than at least one other of the stadium structures 126. In some embodiments, at least one of the stadium structures 126 includes a different (e.g., greater, lower) quantity of steps 134 than at least one other of the stadium structures 126. In some embodiments, the steps 134 of each of the stadium structures 126 are arranged in order, such that steps 134 directly horizontally adjacent (e.g., in the X-direction) one another correspond to preliminary tiers 114 (FIG. 3A) of the preliminary stack structure 104 (FIG. 3A) directly vertically adjacent (e.g., in the Z-direction) one another. In additional embodiments, the steps 134 of at least one of the stadium structures 126 are arranged out of order, such that at least some steps 134 of the stadium structure 126 directly horizontally adjacent (e.g., in the X-direction) one another correspond to preliminary tiers 114 (FIG. 3A) of preliminary stack structure 104 (FIG. 3A) not directly vertically adjacent (e.g., in the Z-direction) one another.

With continued reference to FIG. 3B, for an individual stadium structure 126, the central region 132 thereof may horizontally intervene (e.g., in the X-direction) between and separate the forward staircase structure 130A thereof from the reverse staircase structure 130B thereof. The central region 132 may horizontally neighbor a vertically lowermost step 134 of the forward staircase structure 130A, and may also horizontally neighbor a vertically lowermost step 134 of the reverse staircase structure 130B. A vertical position (e.g., vertical elevation) of the central region 132 of individual stadium structure 126 may define a lower vertical boundary of the stadium structure 126. The central region 132 of an individual stadium structure 126 may have desired horizontal dimensions. In addition, the central region 132 of each of the stadium structures 126 may have substantially the same horizontal dimensions as the central region 132 of each other of the stadium structures 126, or the central region 132 of at least one of the stadium structures 126 may have different horizontal dimensions than the central region 132 of at least one other of the stadium structures 126.

Each stadium structure 126 (including the forward staircase structure 130A, the reverse staircase structure 130B, and the central region 132 thereof) within block region 116 of the preliminary stack structure 104 (FIG. 3A) may individually partially define boundaries (e.g., horizontal boundaries, lower vertical boundaries) of an individual stadium trench 122. The portions of the preliminary stack structure 104 (FIG. 3A) horizontally neighboring an individual stadium structure 126 may also partially define the boundaries of the stadium trench 122 associated with the stadium structure 126. The stadium trench 122 may only vertically extend through preliminary tiers 114 (FIG. 3A) of the preliminary stack structure 104 (FIG. 3A) defining the forward staircase structure 130A and the reverse staircase structure 130B of the stadium structure 126; or may also vertically extend through additional preliminary tiers 114 (FIG. 3A) of the preliminary stack structure 104 (FIG. 3A) not defining the forward staircase structure 130A and the reverse staircase structure 130B of the stadium structure 126, such as additional preliminary tiers 114 (FIG. 3A) of the preliminary stack structure 104 (FIG. 3A) vertically overlying the stadium structure 126. Within the block region 116 (FIG. 3A) of the preliminary stack structure 104 (FIG. 3A), edges of the others of the preliminary tiers 114 (FIG. 3A) of the preliminary stack structure 104 (FIG. 3A) may, for example, define others of the stadium structures 126 vertically overlying and horizontally offset from the stadium structure 126. The stadium trenches 122 may subsequently be filled with one or more dielectric materials, as described in further detail below.

Referring collectively to FIGS. 3A and 3B, columns of the dummy stadium trenches 124 extending in the Y-direction may horizontally overlap, in the X-direction, columns of the stadium trenches 122 extending in the Y-direction. For example, at least some (e.g., each) of the dummy stadium trenches 124 of an individual column of the dummy stadium trenches 124 extending in the Y-direction may horizontally overlap, in the X-direction, at least some (e.g., each) of the stadium trenches 122 of an individual column of the stadium trenches 122 extending in the Y-direction. For an individual column of the dummy stadium trenches 124, at least some (e.g., each) of the dummy stadium trenches 124 thereof may terminate at relatively higher vertical positions (e.g., vertical positions) within the preliminary stack structure 104 than at least some (e.g., each) of the stadium trenches 122 of an individual column of the stadium trenches 122 horizontally overlapping the column of the dummy stadium trenches 124 in the X-direction.

At least some of the dummy stadium trenches 124 may vertically extend to and terminate at different preliminary tiers 114 of the preliminary stack structure 104 than at least some other of the dummy stadium trenches 124. For example, at least some (e.g., each) of the dummy stadium trenches 124 of an individual row of the dummy stadium trenches 124 extending in the X-direction may be formed to terminate at different vertical elevations in the Z-direction than one another. In additional embodiments, at least some (e.g., each) of the dummy stadium trenches 124 of an individual row of the dummy stadium trenches 124 extending in the X-direction are formed to terminate at substantially the same vertical elevation in the Z-direction as one another. In addition, as shown in FIG. 3A, at least some (e.g., each) of the dummy stadium trenches 124 of an individual column of the dummy stadium trenches 124 extending in the Y-direction may terminate at substantially the same vertical elevation in the Z-direction as one another.

The dummy stadium trenches 124 within the non-block region 118 may be formed to vertically terminate at relatively higher vertical elevations within the preliminary stack structure 104 than the stadium trenches 122 within the block region 116 as a result of only forming the openings 117 (FIGS. 2A and 2B) within the block region 116 during the processing stage previously described with reference to FIGS. 2A and 2B. For example, as described in further detail below, by substantially maintaining the masking material 106 (and the isolation material 108, if any) within the non-block region 118 during the processing stage previously described with reference to FIGS. 2A and 2B (so as to not form the openings 117 (FIGS. 2A and 2B) within the non-block region 118), portions of the masking material 106 within the non-block region 118 may delay the removal of portions of the preliminary stack structure 104 within the non-block region 118 relative to the removal of portions of the preliminary stack structure 104 exposed by the openings 117 (FIGS. 2A and 2B) within the block region 116. During an etching process effectuated to form both the stadium trenches 122 within the block region 116 and the dummy stadium trenches 124 within the non-block region 118, one or more etchants employed to form the stadium trenches 122 and the dummy stadium trenches 124 may remove portions of the preliminary stack structure 104 exposed by the openings 117 (FIGS. 2A and 2B) within the block region 116 while being impaired from removing portions of the portions of the preliminary stack structure 104 with the non-block region 118 until the masking material 106 is etched through. As a result, if portions of the microelectronic device structure 100 within the horizontal area of the block region 116 are treated with the etchant concurrently with and for substantially the same duration as additional portions of the microelectronic device structure 100 within the horizontal area of the non-block region 118, the stadium trenches 122 may be formed to be relatively vertically deeper than the dummy stadium trenches 124.

The dummy stadium structures 128 may be positioned within horizontal areas of the dummy stadium trenches 124, and may be exposed by the dummy stadium trenches 124. Referring to FIG. 3B, an individual dummy stadium structure 128 may include a floor region 136 horizontally extending in the X-direction from and between opposite ends of the dummy stadium structure 128 in the X-direction. A vertical position (e.g., vertical elevation) of the floor region 136 of individual dummy stadium structure 128 may define a lower vertical boundary of the dummy stadium structure 128. Unlike the stadium structures 126, the dummy stadium structures 128 may individually be free of (e.g., do not include) staircase structures (e.g., a forward staircase structure, a reverse staircase structure) having steps defined by edges (e.g., horizontal ends) some of the preliminary tiers 114 (FIG. 3A) of the preliminary stack structure 104 (FIG. 3A). However, the opposite ends of an individual dummy stadium structure 128 in the X-direction may be sloped. For example, the opposing ends of a dummy stadium structure 128 may include forward end having positive slope and a reverse end having negative slope. The positive slope of the forward end of an individual dummy stadium structure 128 may be relatively steeper (e.g., greater) than the positive slope of the forward staircase structure 130A of an individual stadium structure 126 horizontally overlapping the dummy stadium structure 128 in the X-direction since the steps 134 of the forward staircase structure 130A of the stadium structure 126 may decrease an angle of inclination of the forward staircase structure 130A of the stadium structure 126 relative to that of the forward end of the dummy stadium structure 128. Furthermore, the negative slope of the reverse end of an individual dummy stadium structure 128 may be relatively steeper (e.g., greater) than the negative slope of the reverse staircase structure 130B of an individual stadium structure 126 horizontally overlapping the dummy stadium structure 128 in the X-direction since the steps 134 of the reverse staircase structure 130B of the stadium structure 126 may decrease an angle of inclination of the reverse staircase structure 130B of the stadium structure 126 relative to that of the reverse end of the dummy stadium structure 128.

Referring collectively to FIGS. 3A and 3B, at least some of the dummy stadium structures 128 may individually have a smaller overall vertical height in the Z-direction than at least some of the stadium structures 126. For example, for an individual dummy stadium structure 128 horizontally overlapping an individual stadium structure 126 in the X-direction, the dummy stadium structure 128 may have a smaller overall vertical height in the Z-direction than the stadium structure 126. The dummy stadium structure 128 may vertically span fewer of the preliminary tiers 114 of the preliminary stack structure 104 than the stadium structure 126. In some embodiments, at least one dummy stadium structure 128 horizontally overlapping at least one stadium structure 126 in the X-direction has an overall vertical height in the Z-direction that is at least 50 percent smaller than an overall vertical height of the at least one stadium structure 126, such as within a range from about 50 percent smaller to about 90 percent smaller, from about 60 percent smaller to about 80 percent smaller, or from about 70 percent smaller to about 80 percent smaller.

For an individual dummy stadium structure 128 horizontally overlapping an individual stadium structure 126 in the X-direction, a vertical position (e.g., vertical elevation) of the floor region 136 thereof may vertically overlie a vertical position (e.g., vertical elevation) of the central region 132 of the stadium structure 126. Put another way, a lower vertical boundary of the dummy stadium structure 128 may vertically overlie a lower vertical boundary of the stadium structure 126. In addition, an overall vertical length in the X-direction of the floor region 136 of the dummy stadium structure 128 may be greater than an overall vertical length in the X-direction of the central region 132 of the stadium structure 126. For example, the floor region 136 of the dummy stadium structure 128 may horizontally overlap the central region 132 and the opposing staircase structures 130 (e.g., the forward staircase structure 130A and the reverse staircase structure 130B) of the stadium structure 126 in the X-direction.

In some embodiments, at least some of the dummy stadium structures 128 are substantially horizontally aligned in the X-direction with at least some of the stadium structures 126. For example, a horizontal center in the X-direction of at least one (e.g., each) dummy stadium structure 128 of an individual column of the dummy stadium structures 128 extending in the Y-direction may be substantially aligned with a horizontal center in the X-direction of at least one (e.g., each) stadium structure 126 of an individual column of the stadium structures 126 extending in the Y-direction. In additional embodiments, a horizontal center in the X-direction of at least one (e.g., each) dummy stadium structure 128 of an individual column of the dummy stadium structures 128 is offset from horizontal center in the X-direction of at least one (e.g., each) stadium structure 126 of an individual column of the stadium structures 126 horizontally overlapping the column of the dummy stadium structures 128 in the X-direction.

With collective reference to FIGS. 3A and 3B, to form the stadium trenches 122 (and, hence, the stadium structures 126) and the dummy stadium trenches 124 (and, hence, the dummy stadium structures 128) a resist material (e.g., a photoresist material) may be formed within the openings 117 (FIGS. 2A and 2B), and then the mask structure 120 may be formed or provided over the resulting resist-filled openings and the isolation material 108. Within a horizontal area of the block region 116 of the preliminary stack structure 104, a group of the apertures in the mask structure 120 may expose the resist-filled openings; and within a horizontal area of the non-block region 118 of the preliminary stack structure 104, an additional group of the apertures in the mask structure 120 may expose the isolation material 108. Thereafter, a material removal process may be effectuated to substantially simultaneously form the stadium trenches 122 and the dummy stadium trenches 124. The material removal process may include a series of processing cycles individually including selectively removing portions of the resist material within the resist-filled openings (e.g., by selectively exposing the portions of the resist material to electromagnetic radiation, and then developing of the portions) to expose underlying portions of the preliminary stack structures 104, and then introducing at least one etchant into the apertures in the mask structure 120. Within a horizontal area of the block region 116 of the preliminary stack structure 104, the etchant may remove exposed portions of at least one preliminary tier 114 of the preliminary stack structure 104. Within the horizontal area of the non-block region 118 of the preliminary stack structure 104, the etchant with remove exposed portions of the isolation material 108 (if present), the masking material 106 (if present), or at least one preliminary tier 114 of the preliminary stack structure 104, depending on how many times the processing cycle has previously been performed (e.g., repeated). As the processing cycle is repeated, vertical depths of preliminary stadium trenches into the preliminary stack structure 104 may be increased and preliminary step profiles may be further enhanced; and vertical depths of preliminary dummy stadium trenches into the isolation material 108, the masking material 106, or the preliminary stack structure 104 may also be increased. The isolation material 108 and the masking material 106 within the non-block region 118 of the preliminary stack structure 104 may delay exposure of portions of the preliminary stack structure 104 within the horizontal area of the non-block region 118 to as compared to additional portions of the preliminary stack structure 104 within the horizontal area of the block region 116. Consequently, following the completion of the material removal process (e.g., following the completion of a desired quantity of processing cycles thereof), the resulting dummy stadium trenches 124 may be relatively vertically shallower than (e.g., not as vertically deep as) the resulting stadium trenches 122. In addition, lower vertical boundaries of the resulting dummy stadium structures 128 may vertically overlie lower vertical boundaries of the resulting stadium structures 126.

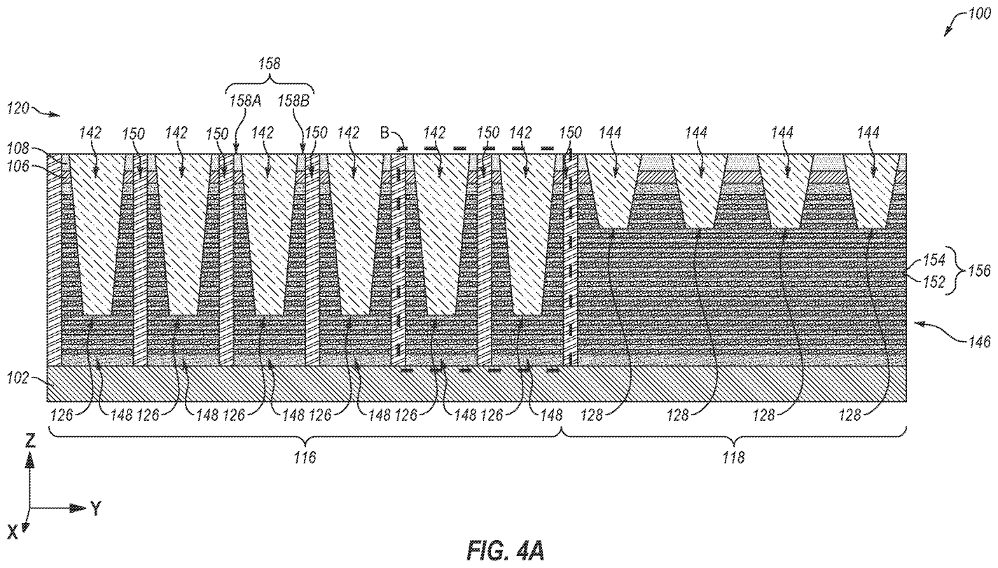

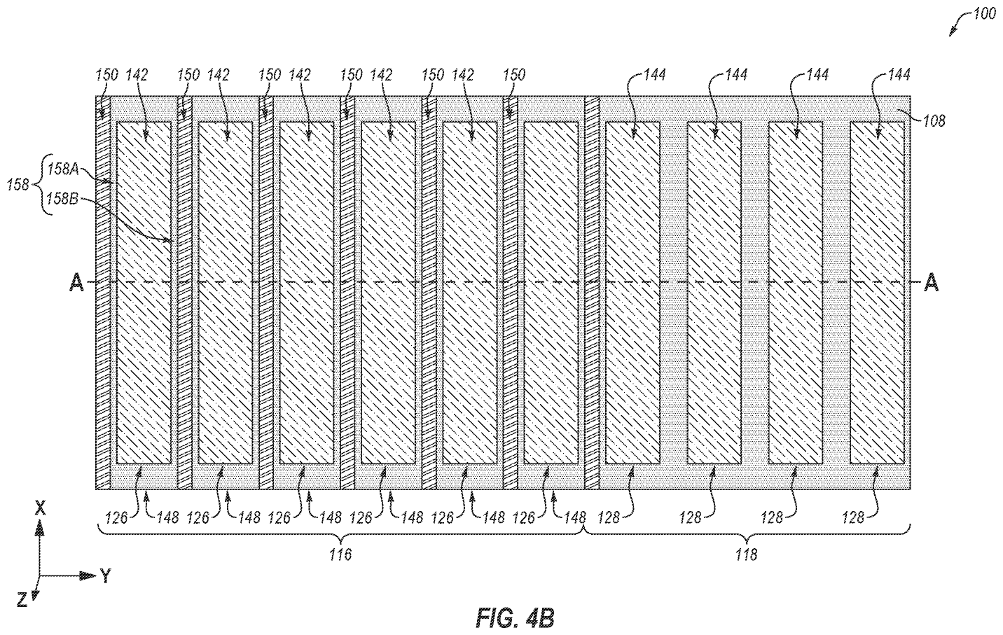

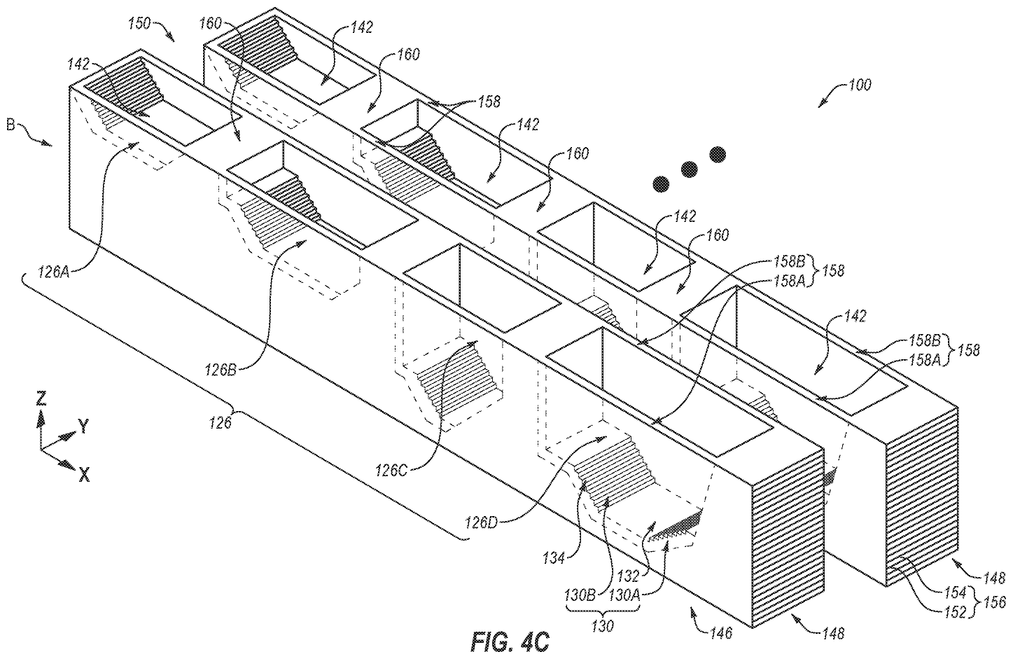

Referring next to FIG. 4A, which is a simplified, longitudinal cross-sectional view of the microelectronic device structure 100 following the processing stage previously described with reference to FIGS. 3A and 3B, remaining portions of the mask structure 120 (FIGS. 3A and 3B) may be removed; the stadium trenches 122 (FIGS. 3A and 3B) and the dummy stadium trenches 124 (FIGS. 3A and 3B) may be filled with at least one dielectric material to form filled stadium trenches 142 and filled dummy stadium trenches 144, respectively; and a stack structure 146 may be formed from the preliminary stack structure 104 (FIGS. 3A and 3B). Within a horizontal area of the block region 116, the stack structure 146 may be formed to include blocks 148 separated from one another by slot structures 150. Within a horizontal area of the non-block region 118, the stack structure 146 may be free of (e.g., may not include) the blocks 148 and the slot structures 150. FIG. 4B is a simplified, partial top-down view of the microelectronic device structure 100 at the processing stage of FIG. 4A, wherein the view of FIG. 4A is about the dashed line A-A depicted in FIG. 4B. FIG. 4C is a simplified, partial perspective view of a portion B (identified with dashed lines in FIG. 4A) of the microelectronic device structure 100 at the processing stage of FIG. 4A.

Referring collectively to FIGS. 4A through 4C, the stack structure 146 may be formed by forming slots to vertically extend completely through the preliminary stack structure 104 (FIG. 3A) within a horizontal area of the block region 116 to form preliminary blocks separated from one another by the slot, and at least partially replacing the sacrificial material 110 (FIG. 3A) of the preliminary tiers 114 (FIG. 3A) of the preliminary stack structure 104 (FIG. 3A) with conductive material through so-called “replacement gate” processing (also referred to herein as “gate last” processing). The stack structure 146 may include tiers 156 formed from the preliminary tiers 114 (FIG. 3A) and individually including conductive material 152 occupying removed portions of the sacrificial material 110 (FIG. 3A), and insulative material 154 vertically neighboring the conductive material 152. The insulative material 154 may comprise portions of the preliminary insulative material 112 (FIG. 3A) of the preliminary stack structure 104 (FIG. 3A) remaining following the replacement gate processing. The replacement gate processing may form the blocks 148 within the block region 116, and each of the blocks 148 may include the conductive material 152 vertically alternating with the insulative material 154. Following the replacement gate processing, the slots may be filled with at least one dielectric material to form the slot structures 150.

The blocks 148 within the block region 116 of the stack structure 146 may be formed to horizontally extend parallel in the X-direction. As used herein, the term “parallel” means substantially parallel. Horizontally neighboring blocks 148 of the stack structure 146 may be separated from one another in the Y-direction orthogonal to the X-direction by the slot structures 150. The slot structures 150 may also horizontally extend parallel in the X-direction. Each of the blocks 148 of the stack structure 146 may exhibit substantially the same geometric configuration (e.g., substantially the same dimensions and substantially the same shape) as each other of the blocks 148, or one or more of the blocks 148 may exhibit a different geometric configuration (e.g., one or more different dimensions and/or a different shape) than one or more other of the blocks 148. In addition, each pair of horizontally neighboring blocks 148 of the stack structure 146 may be horizontally separated from one another by substantially the same distance (e.g., corresponding to a width in the Y-direction of each of the slot structures 150) as each other pair of horizontally neighboring blocks 148 of the stack structure 146, or at least one pair of horizontally neighboring blocks 148 of the stack structure 146 may be horizontally separated from one another by a different distance than that separating at least one other pair of horizontally neighboring blocks 148 of the stack structure 146. In some embodiments, the blocks 148 of the stack structure 146 are substantially uniformly (e.g., substantially non-variably, substantially equally, substantially consistently) sized, shaped, and spaced relative to one another.

Within the block region 116 of the stack structure 146, portions of individual tiers 156 of the stack structure 146 within the horizontal boundaries of the blocks 148 may include the conductive material 152 vertically neighboring the insulative material 154. Put another way, each of the blocks 148 of stack structure may include tiers 156 individually include the conductive material 152 vertically neighboring the insulative material 154. The conductive material 152 may vertically alternate (e.g., may be vertically interleaved) with the insulative material 154 within individual blocks 148 of the stack structure 146 positioned within the horizontal area of the block region 116. In some embodiments, the conductive material 152 is formed of and includes W, and the insulative material 154 is formed of and includes SiO₂. Optionality, at least one liner material (e.g., at least one insulative liner material, at least one conductive liner materials) may be formed around the conductive material 152. The liner material may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). As a non-limiting example, within a horizontal area of an individual block 148, each of the tiers 156 may include AlOₓ (e.g., Al₂O₃) formed directly adjacent the insulative material 154, TiNₓ (e.g., TiN) formed directly adjacent the AlOₓ, and W formed directly adjacent the TiNₓ. Within an individual block 148 of the stack structure 146, edges (e.g., horizontal ends) of at least some of the tiers 156 within the horizontal area of the block 148 may define the steps 134 of the staircase structures 130 (e.g., the forward staircase structure 130A and the reverse staircase structure 130B) of individual stadium structures 126 of the block 148.

Referring to FIG. 4C, the blocks 148 of the stack structure 146 may individually be formed to include a row of the stadium structures 126 (e.g., including a first stadium structure 126A, a second stadium structure 126B vertically below the first stadium structure 126A, a third stadium structure 126C vertically below the second stadium structure 126B, and a fourth stadium structure 126D vertically below the third stadium structure 126C, without limitation), crest regions 160 (e.g., elevated regions), and bridge regions 158 (e.g., additional elevated regions). The crest regions 160 may be horizontally interposed between stadium structures 126 horizontally neighboring one another in the X-direction. The bridge regions 158 may horizontally neighbor opposing sides of individual stadium structures 126 in the Y-direction, and may horizontally extend from and between crest regions 160 horizontally neighboring one another in the X-direction. In FIG. 4C, for clarity and ease of understanding the drawings and associated description, portions (e.g., some of the bridge regions 158 horizontally neighboring first sides of the stadium structures 126 in the Y-direction) of some of the blocks 148 of the stack structure 146 are depicted as transparent to more clearly show the stadium structures 126 distributed within an individual block 148.

As shown in FIG. 4C, the crest regions 160 of an individual block 148 of the stack structure 146 may intervene between and separate stadium structures 126 horizontally neighboring one another in the X-direction. For example, one of the crest regions 160 may intervene between and separate the first stadium structure 126A and the second stadium structure 126B; and an additional one of the crest regions 160 may intervene between and separate the second stadium structure 126B and the third stadium structure 126C. A vertical height of the crest regions 160 in the Z-direction may be substantially equal to a maximum vertical height of the block 148 in the Z-direction; and a horizontal width of the crest regions 160 in the Y-direction may be substantially equal to a maximum horizontal width of the block 148 in the Y-direction. In addition, each of the crest regions 160 may individually exhibit a desired horizontal length in the X-direction. Each of the crest regions 160 of an individual block 148 of the stack structure 146 may exhibit substantially the same horizontal length in the X-direction as each other of the crest regions 160 of the block 148; or at least one of the crest regions 160 of the block 148 may exhibit a different horizontal length in the X-direction than at least one other of the crest regions 160 of the block 148.

Still referring to FIG. 4C, the bridge regions 158 of an individual block 148 of the stack structure 146 may be formed to intervene between and separate the stadium structures 126 of the block 148 from the slot structures 150 horizontally neighboring the block 148 in the Y-direction. For example, for each stadium structure 126 within an individual block 148 of the stack structure 146, a first bridge region 158A may be horizontally interposed in the Y-direction between a first side of the stadium structure 126 and a first of the slot structures 150 horizontally neighboring the block 148; and a second bridge region 158B may be horizontally interposed in the Y-direction between a second side of the stadium structure 126 and a second of the slot structures 150 horizontally neighboring the block 148. The first bridge region 158A and the second bridge region 158B may horizontally extend in parallel in the X-direction. In addition, the first bridge region 158A and the second bridge region 158B may each horizontally extend from and between crest regions 160 of the block 148 horizontally neighboring one another in the X-direction. The bridge regions 158 of the block 148 may be integral and continuous with the crest regions 160 of the block 148. Upper boundaries (e.g., upper surfaces) of the bridge regions 158 may be substantially coplanar with upper boundaries of the crest regions 160. A vertical height of the bridge regions 158 in the Z-direction may be substantially equal to a maximum vertical height of the block 148 in the Z-direction. In addition, each of the bridge regions 158 (including each first bridge region 158A and each second bridge region 158B) may individually exhibit a desired horizontal width in the Y-direction and a desired horizontal length in the X-direction. Each of the bridge regions 158 of the block 148 may exhibit substantially the same horizontal length in the X-direction as each other of the bridge regions 158 of the block 148; or at least one of the bridge regions 158 of the block 148 may exhibit a different horizontal length in the X-direction than at least one other of the bridge regions 158 of the block 148. In addition, each of the bridge regions 158 of the block 148 may exhibit substantially the same horizontal width in the Y-direction as each other of the bridge regions 158 of the block 148; or at least one of the bridge regions 158 of the block 148 may exhibit a different horizontal width in the Y-direction than at least one other of the bridge regions 158 of the block 148.

The blocks 148 and the slot structures 150 may not be formed throughout (e.g., may be substantially omitted from) the non-block region 118 of the stack structure 146. However, one of the slot structures 150 (also referred to herein as an “edge” slot structure 150) may be horizontally interposed, in the Y-direction, between one of the blocks 148 at or most proximate a horizontal boundary in the Y-direction (also referred to herein as an “edge” block 148) of the block region 116 and one of the rows of the dummy stadium structures 128 (also referred to herein as an “edge” row of the dummy stadium structures 128) extending in the X-direction and horizontally neighing the edge block 148 in the Y-direction. The edge slot structure 150 between the edge block 148 and the edge row of the dummy stadium structures 128 may be substantially confined within a horizontal area of the block region 116 of the stack structure 146, may be substantially confined within a horizontal area of the non-block region 118 of the stack structure 146, or may horizontally overlap each of the horizontal area of the block region 116 and the horizontal area of the non-block region 118 of the stack structure 146.

Portions of individual tiers 156 within the non-block region 118 of the stack structure 146 may include the conductive material 152, may include a combination of the conductive material 152 and remaining (e.g., unremoved) portions of the sacrificial material 110 (FIG. 3A), or may be substantially free of the conductive material 152 (e.g., the sacrificial material 110 (FIG. 3A) within the non-block region 118 may not be substantially replaced with the conductive material 152 at the processing stage described with reference to FIGS. 4A through 4C). In some embodiments, within the non-block region 118, horizontal portions of individual tiers 156 of the stack structure 146 horizontally proximate (e.g., in the Y-direction) the edge slot structure 150 (and, hence, horizontally proximate the edge row of the dummy stadium structures 128) include the conductive material 152 vertically neighboring the insulative material 154, and additional horizontal portions of the individual tiers 156 relatively more horizontally distal from the edge slot structure 150 include the sacrificial material 110 (FIG. 3A) vertically neighboring the insulative material 154. Put another way, non-block region 118, portions of stack structure 146 relatively horizontally proximate to the edge slot structure 150 may include the conductive material 152 vertically alternating (e.g., vertically interleaved) with the insulative material 154, and additional portions of stack structure 146 relatively more horizontally distal from the edge slot structure 150 may include the sacrificial material 110 (FIG. 3A) vertically alternating (e.g., vertically interleaved) with the insulative material 154. In additional embodiments, within the non-block region 118, individual tiers 156 of the stack structure 146 include the conductive material 152 at horizontal positions relatively more horizontally distal (e.g., in the Y-direction) from the edge slot structure 150 as well. As a non-limiting example, additional horizontal portions of the individual tiers 156 relatively more horizontally distal from the edge slot structure 150 may include the conductive material 152 continuously horizontally extending thereacross. As another non-limiting example, additional horizontal portions of the individual tiers 156 relatively more horizontally distal from the edge slot structure 150 may include a combination of the conductive material 152 and remaining portions of the sacrificial material 110 (FIG. 3A). Edges (e.g., horizontal ends) of at least some of the tiers 156 within the horizontal area of non-block region 118 may define horizontal boundaries of individual dummy stadium structures 128.

At least some of the dummy stadium structures 128 (e.g., at least the edge row of the dummy stadium structures 128 most horizontally proximate the block region 116 in the Y-direction) within the non-block region 118 may mitigate edge loading effects that may otherwise result in undesirable damage to and/or undesirable defects within at least some of the blocks 148 (e.g., at least the edge block 148 most horizontally proximate the non-block region 118 in the Y-direction). For example, at least the configuration of the edge row of the dummy stadium structures 128, including the dummy stadium structures 128 that are vertically shallow relative to the row of stadium structures 126 of the edge block 148, may shift edge loading effects away from the edge block 148 to the edge row of the dummy stadium structures 128. As a result, undesirable damage to one or more of the bridge regions 158 (e.g., the second bridge region 158B) of at least the edge block 148 may be mitigated (e.g., prevented).

Thus, in accordance with embodiments of the disclosure, a microelectronic device comprises a stack structure comprising a block region and a non-block region. The block region comprises blocks separated from one another in a first horizontal direction by insulative slot structures and each including a vertically alternating sequence of conductive material and insulative material arranged in tiers. At least one of the blocks has stadium structures individually including staircase structures having steps comprising edges of some of the tiers. The non-block region neighbors the block region in the first horizontal direction. The non-block region comprises additional stadium structures individually terminating at a relatively higher vertical position within the stack structure than at least one of the stadium structures at least partially within boundaries thereof in a second horizontal direction orthogonal to the first horizontal direction.

Furthermore, in accordance with embodiments of the disclosure, a method of forming a microelectronic device comprises forming a preliminary stack structure comprising a vertically alternating sequence of sacrificial material and insulative material arranged in tiers. The preliminary stack structure includes a block region and a non-block region neighboring the block region in a first horizontal direction. A masking material is formed over the preliminary stack structure. Openings are formed to vertically extend through a portion of the masking material within a horizontal area of the block region of the preliminary stack structure. Stadium structures are formed at horizontal locations of the openings and individually include staircase structures having steps comprising edges of some of the tiers. Additional stadium structures are formed within the non-block region of the preliminary stack structure. The additional stadium structures individually terminate at a relatively higher vertical position within the preliminary stack structure than at least one of the stadium structures at least partially within boundaries thereof in a second horizontal direction orthogonal to the first horizontal direction. The block region of the preliminary stack structure is divided into blocks separated from one another by slots. At least one of the blocks includes a row of the stadium structures extending in the second horizontal direction. Portions of the sacrificial material within the block region of the preliminary stack structure are replaced with conductive material by way of the slots.

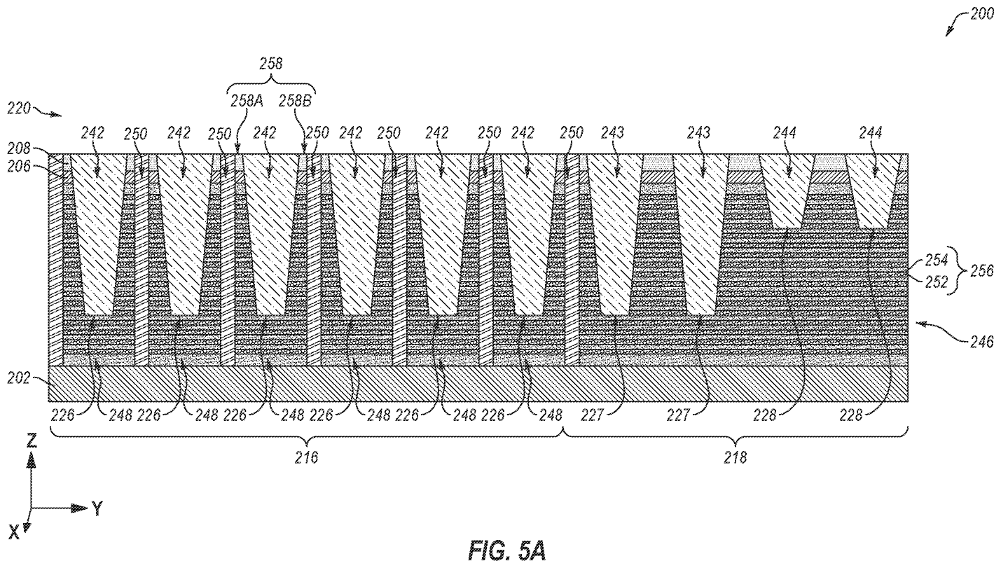

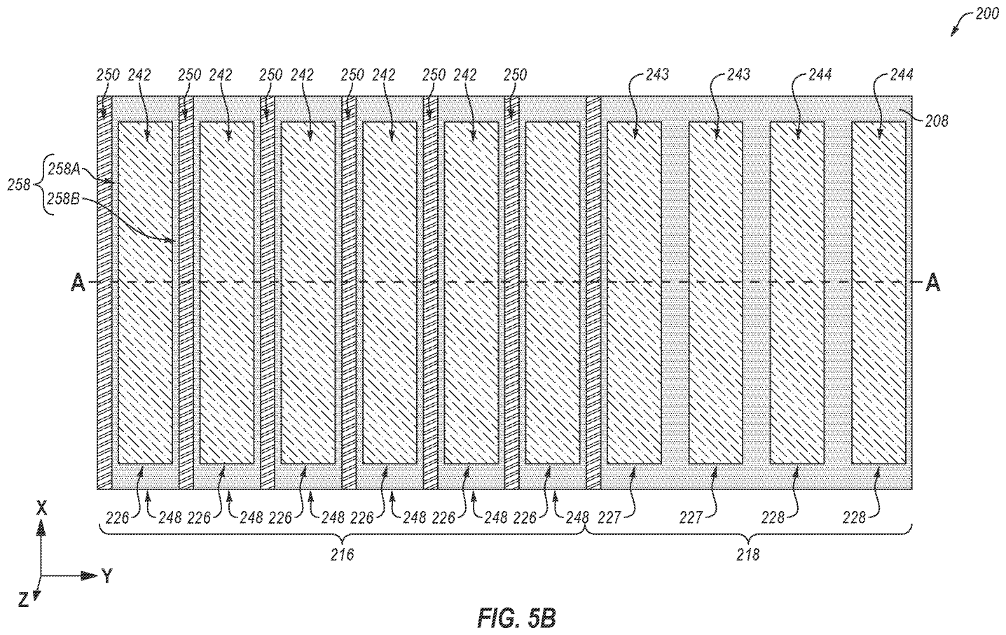

In additional embodiments, the microelectronic device structure 100 may be formed to have a different configuration than that previously described with reference to FIGS. 4A through 4C. The microelectronic device structure 100 may, for example, be formed to exhibit a configuration such as that depicted in FIGS. 5A and 5B and described in further detail below. With the description provided below, it will be readily apparent to one of ordinary skill in the art that the structures and devices described herein may be included in relatively larger structures, devices, and systems.

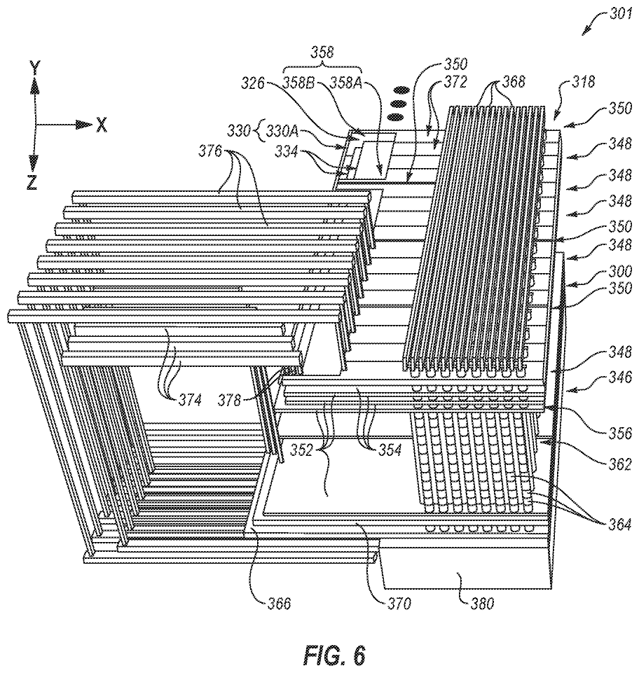

Before referring to FIG. 5A, it will be understood that throughout the FIGS. 5A, 5B, and 6 and the associated description, features (e.g., regions, materials, structures, devices) functionally similar to previously described features (e.g., previously described materials, structures, devices) are referred to with similar reference numerals incremented by 100. To avoid repetition, not all features shown in FIGS. 5A, 5B, and 6 are described in detail herein. Rather, unless described otherwise below, a feature in one or more of FIGS. 5A, 5B, and 6 designated by a reference numeral that is a 100 increment of the reference numeral of a feature previously described with reference to one or more of FIGS. 1A through 4C will be understood to be substantially similar to and have substantially the same advantages as the previously described feature. As a non-limiting example, unless described otherwise below, features designated by the reference numerals 248 (FIGS. 5A and 5B) and 348 (FIG. 6) will be understood to respectively be substantially similar to the blocks 148 previously described herein with reference to FIGS. 4A through 4C. In addition, for clarity and ease of understanding the drawings and related description, some features (e.g., structures, materials, regions, devices) previously described with reference to one or more of FIGS. 1A through 4C are not depicted in one or more FIGS. 5A, 5B, and 6. However, unless described otherwise below, it will be under that any features of the microelectronic device structure 100 at the processing stage previously described with reference to FIGS. 4A through 4C may be included in any of the different configurations described hereinbelow with reference to FIGS. 5A, 5B, and 6.

FIG. 5A depicts a simplified, longitudinal cross-sectional view of a microelectronic device structure 100, in accordance with additional embodiments of the disclosure. The microelectronic device structure 200 may be similar to the microelectronic device structure 100 at the processing stage previously described with reference to FIGS. 4A through 4C, except that, for example, the microelectronic device structure 200 may be formed to include additional dummy stadium structures 227 and additional filled dummy stadium trenches 243 within a horizontal area of the non-block region 218 of the stack structure 246 hereof. FIG. 5B is a simplified, partial top-down view of the microelectronic device structure 200 of FIG. 5A, wherein the view of FIG. 5A is about the dashed line A-A depicted in FIG. 5B.

The additional dummy stadium structures 227 and the additional filled dummy stadium trenches 243 may have configurations substantially similar to the stadium structures 226 and the filled stadium trenches 242, respectively. For example, an individual additional dummy stadium structure 227 within the non-block region 218 may exhibit substantially the same dimensions (e.g., overall vertical height in the Z-direction, overall horizontal width in the Y-direction, overall horizontal length in the X-direction) as an individual stadium structure 226 within the block region 216 that horizontally overlaps the additional dummy stadium structure 227 in the X-direction, and may also include opposing staircase structures (each having steps defined by edges of the tiers 256) and a central region respectively substantially similar to the opposing staircase structures (corresponding to the opposing staircase structures 130 (FIG. 4C) including the steps 134 (FIG. 4C)) and the central region (corresponding to the central region 132 (FIG. 4C)) of the stadium structure 226. Accordingly, the additional dummy stadium structures 227 and the additional filled dummy stadium trenches 243 may have different configurations than the dummy stadium structures 228 and the filled dummy stadium trenches 244 within the horizontal area of the non-block region 218, respectively. An individual additional dummy stadium structure 227 within the non-block region 218 may be relatively vertically deeper in the Z-direction than an individual dummy stadium structure 228 within the non-block region 218 that horizontally overlaps the additional dummy stadium structure 227 in the X-direction.

The additional dummy stadium structures 227 (and, hence, the additional filled dummy stadium trenches 243 within horizontal areas thereof) may be formed to horizontally intervene, in the Y-direction, between the stadium structures 226 within the block region 216 of the stack structure 246 and at least some of the dummy stadium structures 228 within the non-block region 218 of the stack structure 246. For example, at least one row of the additional dummy stadium structures 227 extending in the X-direction may be formed to be horizontally interposed, in the Y-direction, between at least one row of the stadium structures 226 extending in the X-direction and at least one row of the dummy stadium structures 228 extending in the X-direction. In some embodiments, an individual row of the additional dummy stadium structures 227 (also referred to herein and an “edge” row of the additional dummy stadium structures 227) is horizontally interposed, in the Y-direction, between a row of stadium structures 226 of an edge block 248 of the stack structure 246 (e.g., an edge block 248 most horizontally proximate to a horizontal boundary of the block region 216 in the Y-direction) and at least one row of the dummy stadium structures 228. The microelectronic device structure 200 may include multiple (e.g., more than one, such as at least two, at least three, at least four, or at least five) rows of the additional dummy stadium structures 227 (and, hence, the additional filled dummy stadium trenches 243) within the horizontal area of the non-block region 218 of the stack structure 246, or may include only one row of the additional dummy stadium structures 227 within the horizontal area of the non-block region 218 of the stack structure 246. If the microelectronic device structure 200 includes multiple rows of the additional dummy stadium structures 227, each of the multiple rows of the additional dummy stadium structures 227 may be horizontally interposed in the Y-direction between an edge block 248 within the block region 216 of the stack structure 246 and a single row of the dummy stadium structures 228 most horizontally proximate to the edge block 248 in the Y-direction; or at least one of the multiple rows of the additional dummy stadium structures 227 may be horizontally interposed in the Y-direction between two (2) rows of the dummy stadium structures 228 horizontally neighboring one another in the Y-direction.

The additional dummy stadium structures 227 (and, hence, the additional filled dummy stadium trenches 243 within horizontal areas thereof) may be formed through a process substantially similar to that previously described herein for the formation of the stadium structures 126 (FIGS. 4A through 4C), except that the additional dummy stadium structures 227 are formed within the horizontal area of the non-block region 218 rather than the block region 216. For example, during the processing stage previously described herein with reference to FIGS. 2A and 2B, a group of openings (corresponding to the openings 117 (FIGS. 2A and 2B)) may be formed within the non-block region 218, wherein the openings of the group are horizontally positioned at desired locations of the additional dummy stadium structures 227 and vertically extend through portions of the isolation material 208 and the masking material 206 within the non-block region 218. Thereafter, processing stages and processing acts substantially similar to those previously described with reference to FIGS. 3A through 4C may be effectuated to form the microelectronic device structure 200 shown in FIGS. 5A and 5B.

The additional dummy stadium structures 227 and the dummy stadium structures 228 within the non-block region 218 of the stack structure 246 may mitigate edge loading effects that may otherwise result in undesirable damage to and/or undesirable defects within at least some of the edge blocks 248 (e.g., at least the edge block 248 most horizontally proximate the non-block region 218 in the Y-direction) of the stack structure 246. For example, the configurations of the additional dummy stadium structures 227 and the dummy stadium structures 228 may shift edge loading effects away from the edge block 248 that may otherwise result in undesirable damage to one or more of the bridge regions 258 (e.g., the second bridge region 258B) of at least the edge block 248.

Microelectronic device structures (e.g., the microelectronic device structure 100 (FIGS. 4A through 4C); the microelectronic device structure 200 (FIGS. 5A and 5B)) of the disclosure may be included in microelectronic devices of the disclosure. For example, FIG. 6 illustrates a partial cutaway perspective view of a portion of a microelectronic device 301 (e.g., a memory device, such as a 3D NAND Flash memory device) including a microelectronic device structure 300. The microelectronic device structure 300 may be substantially similar to the microelectronic device structure 100 (FIGS. 4A through 4C) or the microelectronic device structure 200 (FIGS. 5A and 5B).

As shown in FIG. 6, in addition to the microelectronic device structure 300, the microelectronic device 301 may further include cell pillar structures 362 vertically extending through individual blocks 348 of the stack structure 346. The cell pillar structures 362 may be positioned within memory array regions of the blocks 348 horizontally offset (e.g., in the X-direction) from the stadium structures 326 within the blocks 348. Intersections of the cell pillar structures 362 and the conductive material 352 of the tiers 356 of the blocks 348 of the stack structure 346 form strings of memory cells 364 vertically extending through each block 348 of the stack structure 346. For each string of memory cells 364, the memory cells 364 thereof may be coupled in series with one another. Within each block 348, the conductive material 352 of some of the tiers 356 thereof may serve as access line structures (e.g., word line structures) for the strings of memory cells 364 within the horizontal area of the block 348. In some embodiments, within each block 348, the memory cells 364 formed at the intersections of the conductive material 352 of some of the tiers 356 and the cell pillar structures 362 comprise so-called “MONOS” (metal-oxide-nitride-oxide-semiconductor) memory cells. In additional embodiments, the memory cells 364 comprise so-called “TANOS” (tantalum nitride-aluminum oxide-nitride-oxide-semiconductor) memory cells, or so-called “BETANOS” (band/barrier engineered TANOS) memory cells, each of which are subsets of MONOS memory cells. In further embodiments, the memory cells 364 comprise so-called “floating gate” memory cells including floating gates (e.g., metallic floating gates) as charge storage structures. The floating gates may horizontally intervene between central structures of the cell pillar structures 362 and the conductive material 352 of the different tiers 356 of the stack structure 346.

The microelectronic device 301 may further include at least one source structure 366, digit line structures 368, one or more first select gates 370 (e.g., lower select gates, source select gate (SGSs)), second select gates 372 (e.g., upper select gates, drain select gates (SGDs)), access line routing structures 374, and select line routing structures 376. The digit line structures 368 may vertically overlie and be coupled to the cell pillar structures 362 (and, hence, the strings of memory cells 364). The second select gates 372 of an individual block 348 interposed between slot structures 350 may be separated from one another by additional dielectric-filled slot structures. The source structure 366 may vertically underlie and be coupled to the cell pillar structures 362 (and, hence, the strings of memory cells 364). In addition, the conductive contact structures 378 may couple various features of the microelectronic device 301 to one another as shown.

The microelectronic device 301 may also include a base control structure 380 positioned vertically below the cell pillar structures 362 (and, hence, the strings of memory cells 364). The base control structure 380 may, for example, be a portion of a relatively larger base structure (e.g., the base structure 102 previously described with reference to FIG. 1A). The base control structure 380 may include at least one control logic region including control logic devices configured to control various operations of other features (e.g., the strings of memory cells 364) of the microelectronic device 301. As a non-limiting example, the control logic region of the base control structure 380 may further include one or more (e.g., each) of charge pumps (e.g., VCCP charge pumps, VNEGWL charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. The control logic region of the base control structure 380 may be coupled to the source structure 366, the digit line structures 368, the access line routing structures 374, and the select line routing structures 376. In some embodiments, the control logic region of the base control structure 380 includes complementary metal-oxide-semiconductor (CMOS) circuitry. In such embodiments, the control logic region of the base control structure 380 may be characterized as having a “CMOS under Array” (“CuA”) configuration.

Thus, in accordance with embodiments of the disclosure, a memory device comprises a stack structure and strings of memory cells. The stack structure comprises a block region and a non-block region. The block region comprises blocks and insulative slot structures. The blocks extend in parallel in a first direction and individually including tiers each comprising conductive material and insulative material vertically neighboring the conductive material. At least one of the blocks comprises stadium structures, crest regions, and bridge regions. The stadium structures individually include staircase structures having steps comprising edges of a group of the tiers. The crest regions are between the stadium structures in the first direction. The bridge regions neighbor the stadium structures in a second direction orthogonal to the first direction. The bridge regions extend in the first direction from between pairs of the crest regions. The insulative slot structures alternate with the blocks in the second direction. The non-block region neighbors the block region in the second direction and comprises additional stadium structures horizontally overlapping the stadium structures in the first direction. Each of the additional stadium structures has a smaller vertical height than a horizontally overlapping one of the stadium structures. The strings of memory cells vertically extend through a portion of the at least one of blocks neighboring an uppermost one of the stadium structures thereof in the first direction.

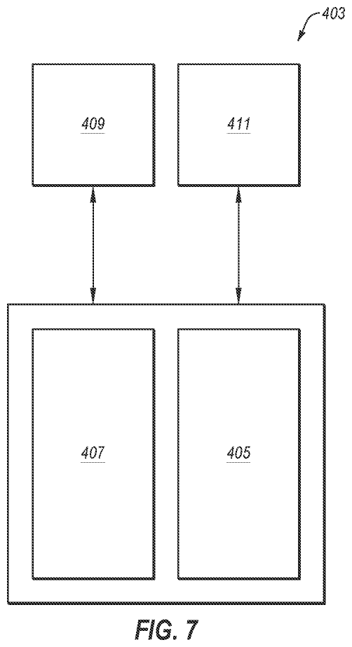

Microelectronic devices structures (e.g., the microelectronic device structure 100 (FIGS. 4A through 4C), the microelectronic device structure 200 (FIGS. 5A and 5B)) and microelectronic devices (e.g., the microelectronic device 301 (FIG. 6)) in accordance with embodiments of the disclosure may be used in embodiments of electronic systems of the disclosure. For example, FIG. 7 is a block diagram of an illustrative electronic system 403 according to embodiments of disclosure. The electronic system 403 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® or SURFACE® tablet, an electronic book, a navigation device, etc. The electronic system 403 includes at least one memory device 405. The memory device 405 may comprise, for example, one or more of a microelectronic device structure (e.g., the microelectronic device structure 100 (FIGS. 4A through 4C), the microelectronic device structure 200 (FIGS. 5A and 5B)) and a microelectronic device (e.g., the microelectronic device 301 (FIG. 6)) previously described herein. The electronic system 403 may further include at least one electronic signal processor device 407 (often referred to as a “microprocessor”). The electronic signal processor device 407 may, optionally, include one or more of a microelectronic device structure (e.g., the microelectronic device structure 100 (FIGS. 4A through 4C), the microelectronic device structure 200 (FIGS. 5A and 5B)) and a microelectronic device (e.g., the microelectronic device 301 (FIG. 6)) previously described herein. While the memory device 405 and the electronic signal processor device 407 are depicted as two (2) separate devices in FIG. 7, in additional embodiments, a single (e.g., only one) memory/processor device having the functionalities of the memory device 405 and the electronic signal processor device 407 is included in the electronic system 403. In such embodiments, the memory/processor device may include one or more of a microelectronic device structure (e.g., the microelectronic device structure 100 (FIGS. 4A through 4C), the microelectronic device structure 200 (FIGS. 5A and 5B)) and a microelectronic device (e.g., the microelectronic device 301 (FIG. 6)) previously described herein. The electronic system 403 may further include one or more input devices 409 for inputting information into the electronic system 403 by a user, such as, for example, a mouse or other pointing device, a keyboard, a touchpad, a button, or a control panel. The electronic system 403 may further include one or more output devices 411 for outputting information (e.g., visual or audio output) to a user such as, for example, a monitor, a display, a printer, an audio output jack, a speaker, etc. In some embodiments, the input device 409 and the output device 411 comprise a single touchscreen device that can be used both to input information to the electronic system 403 and to output visual information to a user. The input device 409 and the output device 411 may communicate electrically with one or more of the memory device 405 and the electronic signal processor device 407.

Thus, in accordance with embodiments of the disclosure, an electronic system comprises an input device, an output device, a processor device operably coupled to the input device and the output device, and a memory device operably coupled to the processor device. The memory device comprises at least one microelectronic device structure comprising a stack structure and strings of memory cells. The stack structure has tiers each comprising conductive material and insulative material vertically neighboring the conductive material. The stack structure comprises a block region and a dummy region. The block region comprises blocks separated from one another by insulative slot structures. At least one of the blocks comprises stadium structures, first elevated regions, and second elevated regions. The stadium structures individually comprise staircase structures having steps comprising edges of some of the tiers of the stack structure. The first elevated regions alternate with the stadium structures in a first horizontal direction. The second elevated regions are integral with the first elevated regions and are interposed between the stadium structures and two of the insulative slot structures in the a second horizontal direction orthogonal to the first horizontal direction. The dummy region neighbors the block region in the second horizontal direction and comprises dummy stadium structures overlapping the stadium structures in the first horizontal direction. At least one of the dummy stadium structures has a smaller vertical height than a horizontally overlapping one of the stadium structures. The strings of memory cells vertically extend through the at least one of the blocks.

The structures, devices, system, and methods of the disclosure advantageously facilitate one or more of improved microelectronic device performance, reduced costs (e.g., manufacturing costs, material costs), increased miniaturization of components, and greater packaging density as compared to conventional structures, conventional devices, conventional systems, and conventional methods. The structures, devices, systems, and methods of the disclosure may also improve scalability, efficiency, and simplicity as compared to conventional structures, conventional devices, conventional systems, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A microelectronic device, comprising:
a stack structure comprising:
a block region comprising:
blocks separated from one another in a first horizontal direction by insulative slot structures and each including a vertically alternating sequence of conductive material and insulative material arranged in tiers, at least one of the blocks having stadium structures individually including staircase structures having steps comprising edges of some of the tiers; and
a non-block region neighboring the block region in the first horizontal direction and comprising:
additional stadium structures individually terminating at a relatively higher vertical position within the stack structure than at least one of the stadium structures at least partially within boundaries thereof in a second horizontal direction orthogonal to the first horizontal direction.

2. The microelectronic device of claim 1, wherein the at least one of the blocks further comprises:
crest regions interposed between the stadium structures in the second horizontal direction; and
bridge regions integral with the crest regions and interposed between the insulative slot structures and the stadium structures the first horizontal direction.

3. The microelectronic device of claim 1, wherein portions of the stack structure within the non-block region substantially continuously extend from and between pairs of the additional stadium structures neighboring one another in the first horizontal direction.

4. The microelectronic device of claim 1, wherein the non-block region of the stack structure is substantially free of the blocks within a horizontal area thereof.

5. The microelectronic device of claim 1, wherein the additional stadium structures comprise columns of the additional stadium structures extending in the first horizontal direction, each of columns of the additional stadium structures substantially aligned with one of the stadium structures of the at least one of the blocks in the second horizontal direction.

6. The microelectronic device of claim 1, wherein the additional stadium structures individually have an overall vertical height within a range from about 50 percent smaller to about 90 percent smaller than an overall vertical height of the at least one of the stadium structures at least partially within the boundaries thereof in the second horizontal direction.

7. The microelectronic device of claim 1, wherein the additional stadium structures individually have an overall vertical height within a range from about 70 percent smaller to about 80 percent smaller than an overall vertical height of the at least one of the stadium structures at least partially within the boundaries thereof in the second horizontal direction.

8. The microelectronic device of claim 1, wherein the additional stadium structures individually have opposing, substantially linear sloped sides in the first horizontal direction.

9. The microelectronic device of claim 8, wherein the additional stadium structures individually have opposing, substantially linear sloped ends in the second horizontal direction.

10. The microelectronic device of claim 1, wherein portions of the stack structure within the non-block region include a vertically alternating sequence of additional insulative material and the insulative material, the additional insulative material positioned at vertical elevations of the conductive material of the tiers of the blocks within the block region of the stack structure.

11. The microelectronic device of claim 1, wherein the non-block region of the stack structure further comprises further stadium structures individually terminating at a relatively lower vertical position within the stack structure than at least one of the additional stadium structures at least partially within boundaries thereof in the second horizontal direction.

12. The microelectronic device of claim 11, wherein at least some of the further stadium structures are interposed, in the first horizontal direction, between at least one of the additional stadium structures most horizontally proximate to the block region of the stack structure and the stadium structures of the at least one of the blocks.

13. The microelectronic device of claim 11, wherein at least one of the further stadium structures has a vertical height substantially equal to a vertical height of one or more of the stadium structures overlapping the at least one of the further stadium structures in the second horizontal direction.

14. A method of forming a microelectronic device, comprising:
forming a preliminary stack structure comprising a vertically alternating sequence of sacrificial material and insulative material arranged in tiers, the preliminary stack structure including a block region and a non-block region neighboring the block region in a first horizontal direction;
forming a masking material over the preliminary stack structure;
forming openings vertically extending through a portion of the masking material within a horizontal area of the block region of the preliminary stack structure;
forming stadium structures at horizontal locations of the openings and individually including staircase structures having steps comprising edges of some of the tiers;
forming additional stadium structures within the non-block region of the preliminary stack structure, the additional stadium structures individually terminating at a relatively higher vertical position within the preliminary stack structure than at least one of the stadium structures at least partially within boundaries thereof in a second horizontal direction orthogonal to the first horizontal direction;
dividing the block region of the preliminary stack structure into blocks separated from one another by slots, at least one of the blocks including a row of the stadium structures extending in the second horizontal direction; and
replacing portions of the sacrificial material within the block region of the preliminary stack structure with conductive material by way of the slots.

15. The method of claim 14, further comprising only forming the openings within the horizontal area of the block region of the preliminary stack structure, an additional portion of the masking material spanning the horizontal area of the non-block region of the preliminary stack structure remaining substantially intact after forming the openings and prior to forming the additional stadium structures.

16. The method of claim 14, wherein forming additional stadium structures within the non-block region of the preliminary stack structure comprises forming the additional stadium structures concurrently with forming the stadium structures within the block region of the preliminary stack structure.

17. The method of claim 16, wherein forming the additional stadium structures concurrently with forming the stadium structures comprises:
filling the openings with resist material to form filled openings;
forming a mask structure over the masking material, the mask structure comprising:
apertures within the horizontal area of the block region of the preliminary stack structure and horizontally overlapping the filled openings; and
additional apertures within a horizontal area of the non-block region of the preliminary stack structure;
removing portions of the resist material of the filled opening and portions of the preliminary stack structure within horizontal areas of the apertures in the mask structure; and
removing portions of the masking material and additional portions of the preliminary stack structure within horizontal areas of the additional apertures in the mask structure.

18. The method of claim 17, wherein the portions of the preliminary stack structure, the portions of the masking material, and the additional portions of the preliminary stack structure are removed by simultaneously providing etchant into the apertures and the additional apertures in the mask structure.

19. The method of claim 14, wherein dividing the block region of the preliminary stack structure into blocks separated from one another by slots comprises forming one of the slots between one of the blocks most horizontally proximate to a horizontal boundary of the block region in the first horizontal direction and at least one of the additional stadium structures most horizontally proximate to the horizontal boundary of the block region in the first horizontal direction.

20. The method of claim 14, further comprising at least partially replacing additional portions of the sacrificial material within the non-block region of the preliminary stack structure with the conductive material.

21. The method of claim 14, further comprising filling the slots with dielectric material after replacing the portions of the sacrificial material within the block region of the preliminary stack structure with the conductive material.

22. A memory device, comprising:
a stack structure comprising:
a block region comprising:
blocks extending in parallel in a first direction and individually including tiers each comprising conductive material and insulative material vertically neighboring the conductive material, at least one of the blocks comprising:
stadium structures individually including staircase structures having steps comprising edges of a group of the tiers;
crest regions between the stadium structures in the first direction; and
bridge regions neighboring the stadium structures in a second direction orthogonal to the first direction, the bridge regions extending in the first direction from between pairs of the crest regions;
insulative slot structures alternating with the blocks in the second direction; and
a non-block region neighboring the block region in the second direction and comprising additional stadium structures horizontally overlapping the stadium structures in the first direction, each of the additional stadium structures having a smaller vertical height than a horizontally overlapping one of the stadium structures; and
strings of memory cells vertically extending through a portion of the at least one of the blocks neighboring an uppermost one of the stadium structures thereof in the first direction.

23. The memory device of claim 22, wherein each of the additional stadium structures has a vertical height within a range of from about 60 percent smaller than to about 80 percent smaller than a vertical height of the horizontally overlapping one of the stadium structures.

24. The memory device of claim 22, wherein the non-block region of the stack structure is substantially free of dielectric filled slot structures horizontally interposed between pairs of the additional stadium structures horizontally neighboring one another the second direction.

25. The memory device of claim 22, wherein at least some of the additional stadium structures within the non-block region of the stack structure have horizontal boundaries at least partially defined by a vertically alternating sequence of additional insulative material and the insulative material within the non-block region, the additional insulative material located at vertical elevations of the conductive material of the tiers of the blocks within the block region of the stack structure.

26. The memory device of claim 22, wherein the non-block region further comprises further stadium structures horizontally overlapping the stadium structures and the additional stadium structures in the first direction, each of the further stadium structures having a larger vertical height than a horizontally overlapping one of the additional stadium structures.

27. An electronic system, comprising:
an input device;
an output device;
a processor device operably coupled to the input device and the output device; and
a memory device operably coupled to the processor device and comprising at least one microelectronic device structure comprising:
a stack structure having tiers each comprising conductive material and insulative material vertically neighboring the conductive material, the stack structure comprising:
a block region comprising blocks separated from one another by insulative slot structures, at least one of the blocks comprising:
stadium structures individually comprising staircase structures having steps comprising edges of some of the tiers of the stack structure;
first elevated regions alternating with the stadium structures in a first horizontal direction; and
second elevated regions integral with the first elevated regions and interposed between the stadium structures and two of the insulative slot structures in a second horizontal direction orthogonal to the first horizontal direction; and
a dummy region neighboring the block region in the second horizontal direction and comprising dummy stadium structures overlapping the stadium structures in the first horizontal direction, at least one of the dummy stadium structures having a smaller vertical height than a horizontally overlapping one of the stadium structures; and
strings of memory cells vertically extending through the at least one of the blocks.

28. The electronic system of claim 27, wherein the memory device comprises a 3D NAND Flash memory device.
